(19) United States
(12) Patent Application Publication
(10) Pub. No.: US 2026/0165066 A1
(43) Pub. Date: Jun. 11, 2026

(54) SUBSTRATE PROCESSING APPARATUS

(71) Applicant: SEMES CO., LTD., Cheonan-si (KR)

(72) Inventor: Chang Suk OH, Cheonan-si (KR)

(21) Appl. No.: 19/363,763

(22) Filed: Oct. 21, 2025

(30) Foreign Application Priority Data
Dec. 11, 2024 (KR) 10-2024-0183830

(51) Int. Cl. H01L 21/67; H01L 21/687

(52) U.S. Cl. CPC H10P 72/0414; H10P 72/76

(57) ABSTRACT

A substrate processing apparatus includes a support unit supporting a substrate; a recovery vessel disposed around the support unit, a mounting base on which the recovery vessel is mounted, and a driving unit moving the mounting base longitudinally and transversely.

### CROSS-REFERENCE TO RELATED APPLICATION(S)

This application claims benefit of priority to Korean Patent Application No. 10-2024-0183830 filed on Dec. 11, 2024 in the Korean Intellectual Property Office, the disclosure of which is incorporated herein by reference in its entirety.

### BACKGROUND

### 1. Field

The present disclosure relates to a substrate processing apparatus for processing a substrate.

### 2. Description of Related Art

To manufacture semiconductor devices, various processes, such as deposition, photolithography, etching, cleaning, and drying, are performed.

Among these processes, the cleaning and drying processes are processes of removing foreign substances and particles from a substrate and then drying the substrate.

The cleaning and drying processes are performed by supplying a processing liquid or gas to a surface or rear surface of the substrate, while rotating the substrate supported on a support unit at high speeds.

Meanwhile, a recovery vessel of a substrate processing apparatus is installed to surround the support unit.

The recovery vessel collects the processing liquid used in the process and fumes generated during the process to prevent the same from splashing or leaking.

However, removal of the recovery vessel for maintenance or replacement is typically performed manually by an operator.

Since the removal and assembly of the recovery vessel is performed manually within a narrow workspace of the substrate processing apparatus, the operation may not be smoothly performed and there is a risk of safety accidents.

### PRIOR ART DOCUMENT

### Patent Document

(Patent Document 1) Korean Application Publication No. 10-2023-0029173

### SUMMARY

An aspect of the present disclosure is to provide a substrate processing apparatus in which a recovery vessel may be removed smoothly and easily.

According to an aspect of the present disclosure, a substrate processing apparatus includes: a support unit supporting a substrate; a recovery vessel disposed around the support unit; a mounting base on which the recovery vessel is mounted; and a driving unit moving the mounting base longitudinally and transversely.

The driving unit may include: a longitudinal driving member longitudinally moving the mounting base; and a transverse driving member installed in the longitudinal driving unit and transversely moving the mounting base.

The longitudinal driving member may include: a support supporting the mounting base; and a first cylinder connected to the support and disposed longitudinally to raise and lower the support.

The mounting base may be installed to move transversely on the support, and the transverse driving member may include a second cylinder connected to the mounting base and disposed transversely on a sidewall of the support to move the mounting base transversely.

The mounting base may be formed with a peripheral wall to fix a position of the recovery vessel, and a hinged door is installed on the peripheral wall to be opened in a removal direction when the recovery vessel is removed transversely and to be close and locked when the recovery vessel is mounted.

The substrate processing apparatus may further include a nozzle unit installed on the support unit and configured to rotate in conjunction with a longitudinal movement of the recovery vessel.

The nozzle unit may include: a bevel cleaning nozzle connected to a cleaning solution supply line; a nozzle case to which the bevel cleaning nozzle is fixed, the nozzle case being rotatably installed on the support unit; and a torsion spring installed on the support unit and providing elasticity to the nozzle case so that the nozzle case is vertically disposed, and when the recovery vessel is lowered, the torsion spring is compressed, and when the recovery vessel is raised, the compression on the torsion spring is released.

The recovery vessel may include a pressing portion pressing one end portion of the nozzle case, and
when pressure of the pressing portion against the one end portion of the nozzle case is released due to rise of the recovery vessel, the nozzle case may rotate forwardly and may be vertically disposed due to elastic force of the torsion spring, and when the pressing portion presses the one end portion of the nozzle case due to lowering of the recovery vessel, the nozzle case may rotate reversely and may be horizontally disposed.

The substrate processing apparatus may further include: an elastic valve having an elastic valve body installed in the recovery vessel and a valve head connected to the valve body and closing a drain hole of the recovery vessel by elastic force of the valve body; and a vertical pin installed in the drain port disposed below the recovery vessel to cover the drain hole and pushing the valve head upwardly when the recovery vessel is lowered to open the drain hole.

According to another aspect of the present disclosure, a substrate processing apparatus includes: a processing chamber; a support unit disposed within the processing chamber and supporting a substrate; a recovery vessel disposed around the support unit; a mounting base on which the recovery vessel is mounted; and a driving unit longitudinally and transversely moving the mounting base, wherein the driving unit includes: a support on which the mounting base is mounted to move transversely; a first cylinder connected to the support and longitudinally disposed to raise and lower the support; and a second cylinder connected to the mounting base and transversely disposed on a sidewall of the support to transversely move the mounting base.

According to another aspect of the present disclosure, a substrate processing apparatus includes: a processing chamber; a support unit disposed within the processing chamber and supporting a substrate; a recovery vessel disposed around the support unit; a mounting base on which the recovery vessel is mounted; driving unit longitudinally and transversely moving the mounting base; a nozzle unit disposed on the support unit and configured to rotate in conjunction with a longitudinal movement of the recovery vessel; an elastic valve having an elastic valve body installed in the recovery vessel and a valve head connected to the valve body and closing a drain hole of the recovery vessel by elastic force of the valve body; and a vertical pin installed in the drain port disposed below the recovery vessel to cover the drain hole and pushing the valve head upwardly when the recovery vessel is lowered to open the drain hole.

### BRIEF DESCRIPTION OF DRAWINGS

The above and other aspects, features, and advantages of the present disclosure will be more clearly understood from the detailed following description, taken in conjunction with the accompanying drawings, in which:

FIG. 1 is a diagram illustrating a substrate processing apparatus according to an embodiment of the present disclosure;

FIGS. 2 to 4 are diagrams illustrating a process of removing a recovery vessel of the substrate processing apparatus of FIG. 1;

FIG. 5 is a diagram illustrating rotation of a bevel cleaning nozzle when the recovery vessel of the substrate processing apparatus of FIG. 2 is raised to be removed;

FIG. 6 is a diagram illustrating the bevel cleaning nozzle rotating in reverse when the recovery vessel of FIG. 5 is lowered to be reinstalled around a support unit;

FIG. 7 is a diagram illustrating an elastic valve closing a drain hole of the recovery vessel of the substrate processing apparatus of FIG. 2 when the recovery vessel is raised to be removed; and

FIG. 8 is a diagram illustrating the elastic valve opening the drain hole of the recovery vessel of FIG. 7 when the recovery vessel is lowered to be installed around the support unit.

### DETAILED DESCRIPTION

Hereinafter, embodiments will be described in detail with reference to the accompanying drawings such that they may be easily practiced by those skilled in the art to which the present disclosure pertains. In describing the present disclosure, if a detailed explanation for a related known function or construction is considered to unnecessarily divert the gist of the present disclosure, such explanation 20 will be omitted but would be understood by those skilled in the art. Also, similar reference numerals are used for the similar parts throughout the specification. In this disclosure, terms, such as “above,” “upper portion,” “upper surface,” “below,” “lower portion,” “lower surface,” “lateral surface,” and the like, are determined based on the drawings, and in actuality, the terms may be changed according to a direction in which a device or an element is disposed.

It will be understood that when an element is referred to as being “connected to” another element, it may be directly connected to the other element or intervening elements may also be present. In contrast, when an element is referred to as being “directly connected to” another element, no intervening elements are present. In addition, unless explicitly described to the contrary, the word “comprise” and variations, such or as “comprises” “comprising,” will be understood to imply the inclusion of stated elements but not the exclusion of any other elements.

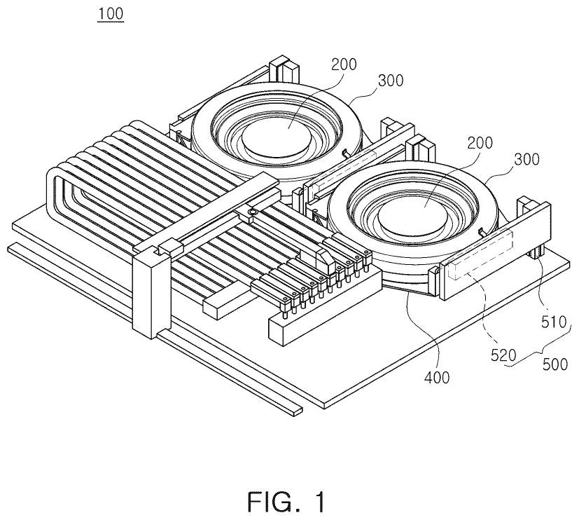

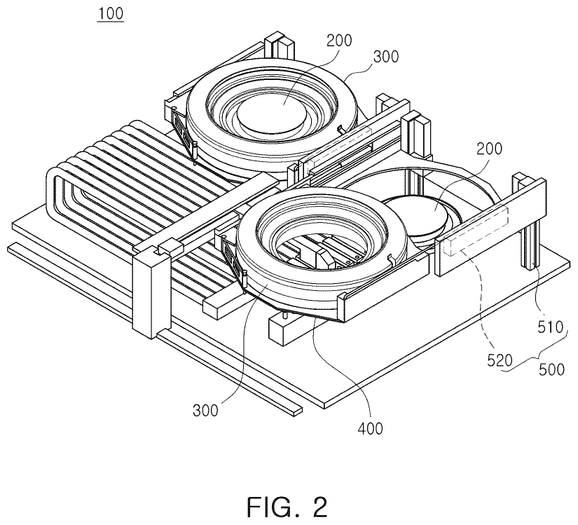

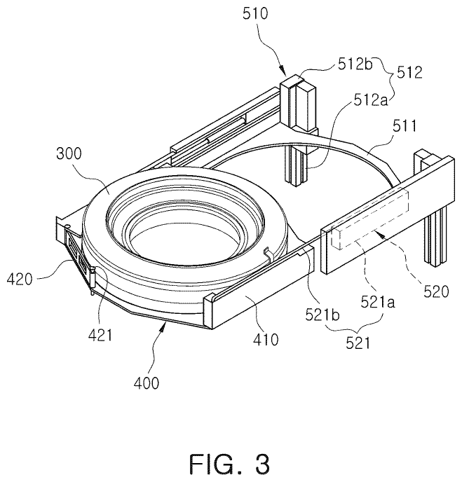

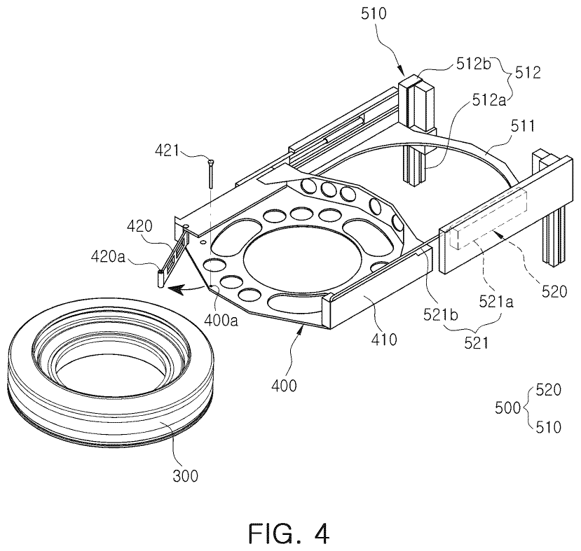

FIG. 1 is a diagram illustrating a substrate processing apparatus according to an embodiment of the present disclosure, and FIGS. 2 to 4 are diagrams illustrating a process of removing a recovery vessel of the substrate processing apparatus of FIG. 1.

Referring to the drawings, a substrate processing apparatus according to an embodiment of the present disclosure includes a processing chamber 100, a support unit 200, a recovery vessel 300, a mounting base 400, and a driving unit 500.

The processing chamber 100 is configured to process a substrate (not shown) therein.

Furthermore, the support unit 200 is disposed within the processing chamber 100 and supports the substrate.

Furthermore, the recovery vessel 300 is disposed around the support unit 200 and has a processing space therein in which the substrate is processed.

The mounting base 400 allows the recovery vessel 300 to be mounted thereon. The mounting base 400 may include a peripheral wall 410 formed at the edge thereof to stably maintain the recovery vessel 300 in a mounted state.

That is, the mounting base 400 may be provided with the peripheral wall 410 to secure the recovery vessel 300 in place.

A hinged door 420 may be installed on the peripheral wall 410 and is opened in a removal direction when the recovery vessel 300 is removed in a horizontal direction and is closed and locked when the recovery vessel 300 is mounted. A door hole 420a may be formed in the hinged door 420, a bottom hole 400a may be formed in the bottom of the mounting base 400, and a locking pin 421 may be inserted into and disposed in the door hole 420a and the bottom hole 400a, thereby locking the hinged door 420.

Meanwhile, the driving unit 500 moves the mounting base 400 longitudinally and transversely

Specifically, the driving unit 500 may include a longitudinal driving member 510 and a transverse driving member 520.

The longitudinal driving member 510 is configured to move the mounting base 400 longitudinally. That is, the longitudinal driving member 510 is configured to raise and lower the mounting base 400.

The longitudinal driving member 510 may include a support 511 and a first cylinder 512.

The support 511 supports the mounting base 400. The support 511 may have an appropriately shaped structure so that the mounting base 400 is stably mounted.

Furthermore, the first cylinder 512 may be connected to the support 511 and may be arranged longitudinally to raise and lower the support 511. For example, the first cylinder 512 may include a first cylinder body 512a installed on the bottom of the processing chamber 100 and a first cylinder rod 512b installed on the first cylinder body 512a so as to be extendable longitudinally.

Also, the mounting base 400 may be installed on the support 511 so as to be movable transversely. That is, the mounting base 400 may be installed so that the support 511 is movable transversely in a removal direction of the recovery vessel 300. For example, the mounting base 400 may be provided with a guide rail to guide a transverse movement of the support 511.

The transverse driving member 520 is installed on the longitudinal driving unit 510 and is configured to move the mounting base 400 transversely.

The transverse driving member 520 may include a second cylinder 521.

The second cylinder 521 may be connected to the mounting base 400 and may be disposed transversely on the sidewall of the support 511 to move the mounting base 400 transversely. For example, in the second cylinder 521, a second cylinder body 521a may be installed on an inner surface of the peripheral wall 410 of the mounting base 400 and a second cylinder rod 521b may be installed on the second cylinder body 521a so as to be extendable transversely.

As described above, in the present disclosure, since the driving unit 500 includes the longitudinal driving member 510 and the transverse driving member 520 to automatically, rather than manually, move the mounting base 400 both longitudinally and transversely, the recovery vessel 300 may be smoothly and easily removed.

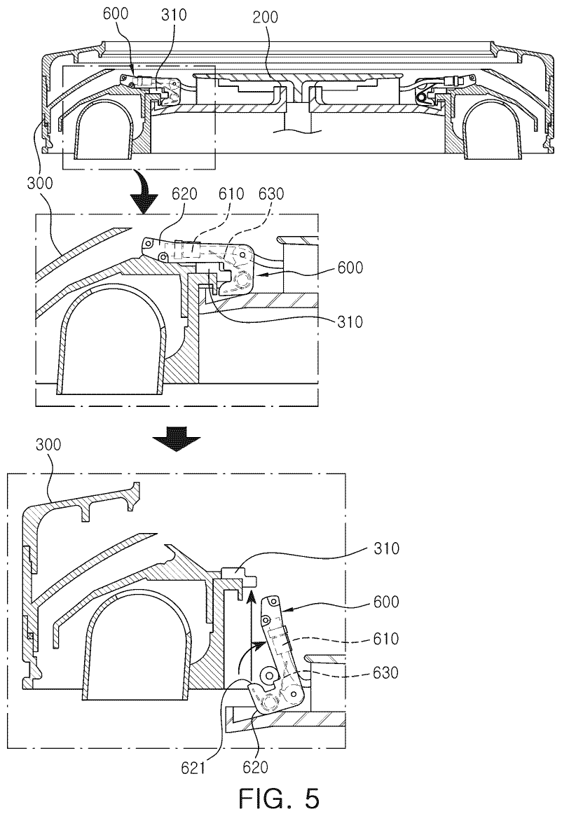

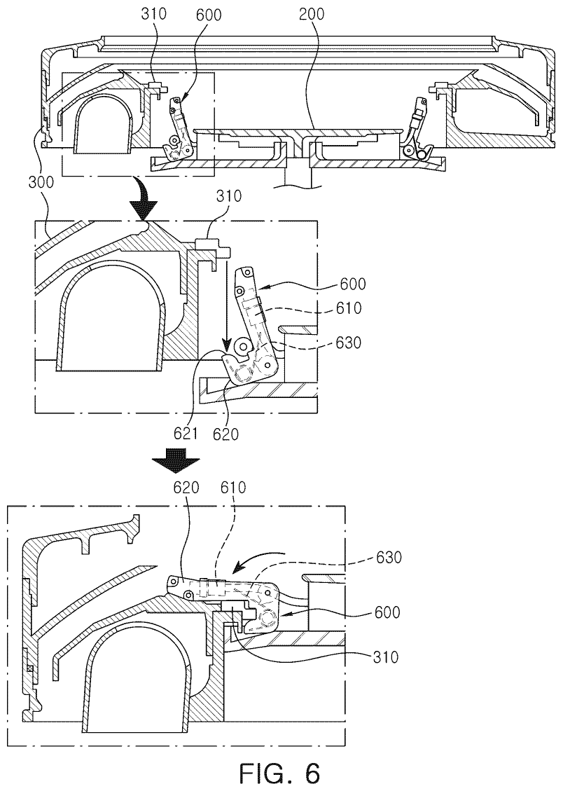

FIG. 5 is a diagram illustrating a nozzle unit rotating when the recovery vessel of the substrate processing apparatus of FIG. 2 is raised for installation. FIG. 6 is a diagram illustrating the nozzle unit rotating in reverse when the recovery vessel of FIG. 5 is lowered for installation around the support unit.

The edge of the upper surface and the edge of the lower surface of the substrate have an inclined shape, which is referred to as a bevel region. The bevel region corresponds to approximately 1 to 3 mm from the outermost portion of the substrate, and no circuit pattern is formed in the bevel region.

However, when a deposition or etching process is performed, a thin film is formed in the bevel region, and various chemicals used in the processing come into contact therewith. The thin film and chemicals remaining in the bevel region may not only be unnecessary but may also become a source of contaminants and affect adjacent circuit patterns, increasing a defect rate.

To address this issue, the present disclosure may further include a nozzle unit 600, as illustrated in FIGS. 5 and 6, to clean the bevel region of the substrate.

The nozzle unit 600 may be installed on the support unit 200 and may be configured to rotate in conjunction with a longitudinal movement of the recovery vessel 300.

Specifically, the nozzle unit 600 may include a bevel cleaning nozzle 610, a nozzle case 620, and a torsion spring 630.

The bevel cleaning nozzle 610 may be connected to a cleaning solution supply line. A cleaning solution supplied through the cleaning solution supply line may be discharged to the edge of the substrate through the bevel cleaning nozzle 610.

Furthermore, the nozzle case 620 may secure the bevel cleaning nozzle 610 and may be rotatably installed on the support unit 200. The recovery vessel 300 may be provided with a pressing portion 310 pressing one end portion 621 of the nozzle case 620.

The torsion spring 630 may be installed on the support unit 200 and provide elasticity to the nozzle case 620 so that the nozzle case 620 may be vertically disposed.

Specifically, when the recovery vessel 300 is lowered, the torsion spring 630 is compressed, and when the recovery vessel 300 is raised, the pressure on the torsion spring 630 is released.

Specifically, as illustrated in FIG. 5, when the pressing portion 310 is raised due to the rise of the recovery vessel 300, the nozzle case 620 may rotate forwardly so as to be vertically disposed due to the elasticity of the torsion spring 630.

In other words, when the recovery vessel 300 is raised to be removed from the processing chamber 100, the pressing portion 310 of the recovery vessel 300 is raised, and accordingly, the pressure of the pressing portion 310 against one end portion 621 of the nozzle case 620 is released.

Accordingly, the nozzle case 620 rotates forwardly and disposed vertically due to the elastic force of the torsion spring 630.

As a result, when the recovery vessel 300 is raised to be removed, the bevel cleaning nozzle 610 automatically does not interfere with the movement of the recovery vessel 300.

Conversely, as illustrated in FIG. 6, the lowering of the recovery vessel 300 may cause the pressing portion 310 to push against one end portion 621 of the nozzle case 620, and accordingly, the nozzle case 620 may rotate reversely so as to be disposed horizontally.

In other words, when the recovery vessel 300 is lowered to be installed in the processing chamber 100, the pressing portion 310 of the recovery vessel 300 presses one end portion 621 of the nozzle case 620. When one end portion 621 of the nozzle case 620 is pressed by the pressing portion 310, the nozzle case 620 rotates reversely as the torsion spring 630 resists the elastic force, so as to be disposed horizontally.

As a result, when the recovery vessel 300 is lowered to be installed, the bevel cleaning nozzle 610 automatically forms a configuration to discharge the cleaning solution onto the edge of the lower surface of the substrate.

As described above, in the present disclosure, since the nozzle unit 600 includes the torsion spring 630, when the recovery vessel 300 is raised, the bevel cleaning nozzle 610 may automatically rotate not to interfere with the movement of the recovery vessel 300, thereby smoothly and easily remove the recovery vessel 300.

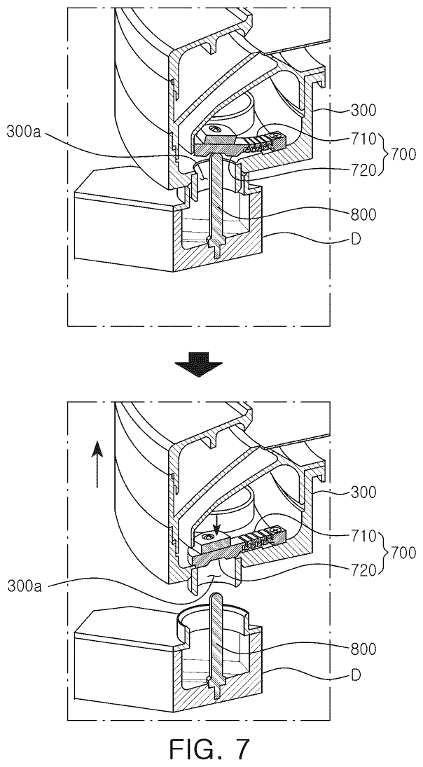

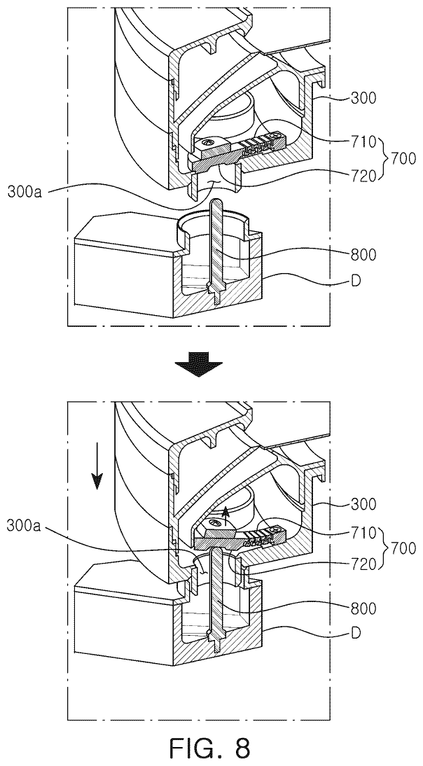

FIG. 7 is a diagram illustrating an elastic valve closing a drain hole of the recovery vessel of the substrate processing apparatus of FIG. 2 when the recovery vessel is raised to be removed, and FIG. 8 is a diagram illustrating the elastic valve opening the drain hole of the recovery vessel of FIG. 7 when the recovery vessel is lowered to be installed around the support unit.

Referring to the drawings, the present disclosure may further include an elastic valve 700 and a vertical pin 800.

The elastic valve 700 has a valve body 710 and a valve head 720.

The valve body 710 is installed in the recovery vessel 300 and has an elastic structure.

For example, as illustrated in the drawing, the valve body 710 adopts a corrugated structure, so as to be bent when external pressure is applied and to remain in the bent state when the external pressure is maintained.

Furthermore, the valve head 720 is connected to the valve body 710 and has a structure of closing the drain hole 300a of the recovery vessel 300 by the elastic force of the valve body 710.

The valve head 720 has a size and shape to cover the drain hole 300a of the recovery vessel 300 to correspond to the drain hole 300a and may move toward the drain hole 300a by the valve body 710 providing elasticity to block the drain hole 300a.

The vertical pin 800 is installed in the drain port D.

Here, the drain port D is disposed below the recovery vessel 300 and covers the drain hole 300a.

When the recovery vessel 300 is lowered, the vertical pin 800 pushes the valve head 720 upwardly, thereby opening the drain hole 300a.

Specifically, as illustrated in FIG. 7, when the vertical pin 800 installed in the drain port D is fixed in position and the recovery vessel 300 is raised for removal, the elastic valve 700 closes the drain hole 300a of the recovery vessel 300 by elastic force.

Conversely, as illustrated in FIG. 8, when the recovery vessel 300 is lowered for installation, if the drain hole 300a is lowered toward the vertical pin 800, the vertical pin 800 pushes the valve head 720 upwardly to separate it from the drain hole 300a, thereby opening the drain hole 300a.

That is, the vertical pin 800 remains fixed in its position while installed in the drain port Dm, and when the recovery vessel 300 is lowered toward the vertical pin 800, the vertical pin 800 pushes the valve head 720 upwardly to separate it from the drain hole 300a, thereby opening the drain hole 300a.

Accordingly, the drain hole 300a of the recovery vessel 300 may automatically communicate with the drain port D.

As described above, in the present disclosure, since the elastic valve 700 and the vertical pin 800 are provided, when the recovery vessel 300 is raised, the elastic valve 700 is released from the upward pressure of the vertical pin 800 and covers the drain hole 300a, thereby automatically blocking the drain hole 300a of the recovery vessel 300, and thus, contaminants within the recovery vessel 300 may be prevented from flowing out.

The substrate processing apparatus according to an embodiment of the present disclosure includes the driving unit, and thus, the recovery vessel may be removed smoothly and easily.

Furthermore, in the present disclosure, since the nozzle unit includes the torsion spring, when the recovery vessel is raised, the bevel cleaning nozzle may automatically rotate not to interfere with the movement of the recovery vessel, thereby removing the recovery vessel smoothly and easily.

Also, in the present disclosure, since the elastic valve and the vertical pin are provided, when the recovery vessel is raised, the elastic valve may be released from the upward pressure of the vertical pin and covers the drain hole, thereby automatically blocking the drain hole of the recovery vessel, and thus, contaminants within the recovery vessel may be prevented from flowing out.

While example embodiments have been shown and described above, it will be apparent to those skilled in the art that modifications and variations could be made without departing from the scope of the present disclosure as defined by the appended claims.

What is claimed is:

1. A substrate processing apparatus comprising:
a support unit supporting a substrate;
a recovery vessel disposed around the support unit;
a mounting base on which the recovery vessel is mounted; and
a driving unit moving the mounting base longitudinally and transversely.

2. The substrate processing apparatus of claim 1, wherein the driving unit includes:
a longitudinal driving member longitudinally moving the mounting base; and
a transverse driving member installed in the longitudinal driving unit and transversely moving the mounting base.

3. The substrate processing apparatus of claim 2, wherein the longitudinal driving member includes:
a support supporting the mounting base; and
a first cylinder connected to the support and disposed longitudinally to raise and lower the support.

4. The substrate processing apparatus of claim 3, wherein the mounting base is installed to move transversely on the support, and the transverse driving member includes a second cylinder connected to the mounting base and disposed transversely on a sidewall of the support to move the mounting base transversely.

5. The substrate processing apparatus of claim 1, wherein the mounting base is formed with a peripheral wall to fix a position of the recovery vessel, and a hinged door is installed on the peripheral wall to be opened in a removal direction when the recovery vessel is removed transversely and to be close and locked when the recovery vessel is mounted.

6. The substrate processing apparatus of claim 1, further comprising a nozzle unit installed on the support unit and configured to rotate in conjunction with a longitudinal movement of the recovery vessel.

7. The substrate processing apparatus of claim 6, wherein
the nozzle unit includes:
a bevel cleaning nozzle connected to a cleaning solution supply line;
a nozzle case to which the bevel cleaning nozzle is fixed, the nozzle case being rotatably installed on the support unit; and
a torsion spring installed on the support unit and providing elasticity to the nozzle case so that the nozzle case is vertically disposed, and
when the recovery vessel is lowered, the torsion spring is compressed, and when the recovery vessel is raised, the compression on the torsion spring is released.

8. The substrate processing apparatus of claim 7, wherein
the recovery vessel includes a pressing portion pressing one end portion of the nozzle case, and
when pressure of the pressing portion against the one end portion of the nozzle case is released due to rise of the recovery vessel, the nozzle case rotates forwardly and is vertically disposed due to elastic force of the torsion spring, and
when the pressing portion presses the one end portion of the nozzle case due to lowering of the recovery vessel, the nozzle case rotates reversely and is horizontally disposed.

9. The substrate processing apparatus of claim 1, further comprising:
an elastic valve having an elastic valve body installed in the recovery vessel and a valve head connected to the valve body and closing a drain hole of the recovery vessel by elastic force of the valve body; and
a vertical pin installed in a drain port disposed below the recovery vessel to cover the drain hole and pushing the valve head upwardly when the recovery vessel is lowered to open the drain hole.

10. A substrate processing apparatus comprising:
a processing chamber;
a support unit disposed within the processing chamber and supporting a substrate;
a recovery vessel disposed around the support unit;
a mounting base on which the recovery vessel is mounted; and
a driving unit longitudinally and transversely moving the mounting base,
wherein the driving unit includes:
a support on which the mounting base is mounted to move transversely;
a first cylinder connected to the support and longitudinally disposed to raise and lower the support; and
a second cylinder connected to the mounting base and transversely disposed on a sidewall of the support to transversely move the mounting base.

11. The substrate processing apparatus of claim 10, wherein the mounting base is formed with a peripheral wall to fix a position of the recovery vessel, and a hinged door is installed on the peripheral wall to be opened in a removal direction when the recovery vessel is removed transversely and to be close and locked when the recovery vessel is mounted.

12. The substrate processing apparatus of claim 10, wherein a nozzle unit installed on the support unit and configured to rotate in conjunction with a longitudinal movement of the recovery vessel.

13. The substrate processing apparatus of claim 12, wherein
the nozzle unit includes:
a bevel cleaning nozzle connected to a cleaning solution supply line;
a nozzle case to which the bevel cleaning nozzle is fixed, the nozzle case being rotatably installed on the support unit; and
a torsion spring installed on the support unit and providing elasticity to the nozzle case so that the nozzle case is vertically disposed, and
when the recovery vessel is lowered, the torsion spring is compressed, and when the recovery vessel is raised, the compression on the torsion spring is released.

14. The substrate processing apparatus of claim 13, wherein
the recovery vessel includes a pressing portion pressing one end portion of the nozzle case, and
when pressure of the pressing portion against the one end portion of the nozzle case is released due to rise of the recovery vessel, the nozzle case rotates forwardly and is vertically disposed due to elastic force of the torsion spring, and
when the pressing portion presses the one end portion of the nozzle case due to lowering of the recovery vessel, the nozzle case rotates reversely and is horizontally disposed.

15. The substrate processing apparatus of claim 10, wherein
an elastic valve having an elastic valve body installed in the recovery vessel and a valve head connected to the valve body and closing a drain hole of the recovery vessel by elastic force of the valve body; and
a vertical pin installed in a drain port disposed below the recovery vessel to cover the drain hole and pushing the valve head upwardly when the recovery vessel is lowered to open the drain hole.

16. A substrate processing apparatus comprising:
a processing chamber;
a support unit disposed within the processing chamber and supporting a substrate;
a recovery vessel disposed around the support unit;
a mounting base on which the recovery vessel is mounted; and
a driving unit longitudinally and transversely moving the mounting base;
a nozzle unit disposed on the support unit and configured to rotate in conjunction with a longitudinal movement of the recovery vessel;
an elastic valve having an elastic valve body installed in the recovery vessel and a valve head connected to the valve body and closing a drain hole of the recovery vessel by elastic force of the valve body; and
a vertical pin installed in a drain port disposed below the recovery vessel to cover the drain hole and pushing the valve head upwardly when the recovery vessel is lowered to open the drain hole.

17. The substrate processing apparatus of claim 16, wherein
the driving unit includes:
a support on which the mounting base is installed to move transversely;
a first cylinder connected to the support and disposed longitudinally to raise and lower the support; and
a second cylinder connected to the mounting base and disposed transversely on a sidewall of the support to move the mounting base transversely.

18. The substrate processing apparatus of claim 16, wherein the mounting base is formed with a peripheral wall to fix a position of the recovery vessel, and a hinged door is installed on the peripheral wall to be opened in a removal direction when the recovery vessel is removed transversely and to be close and locked when the recovery vessel is mounted.

19. The substrate processing apparatus of claim 16, wherein
the nozzle unit includes:
a bevel cleaning nozzle connected to a cleaning solution supply line;
a nozzle case to which the bevel cleaning nozzle is fixed, the nozzle case being rotatably installed on the support unit; and
a torsion spring installed on the support unit and providing elasticity to the nozzle case so that the nozzle case is vertically disposed, and
when the recovery vessel is lowered, the torsion spring is compressed, and when the recovery vessel is raised, the compression on the torsion spring is released.

20. The substrate processing apparatus of claim 19, wherein
the recovery vessel includes a pressing portion pressing one end portion of the nozzle case, and
when pressure of the pressing portion against the one end portion of the nozzle case is released due to rise of the recovery vessel, the nozzle case rotates forwardly and is vertically disposed due to elastic force of the torsion spring, and
when the pressing portion presses the one end portion of the nozzle case due to lowering of the recovery vessel, the nozzle case rotates reversely and is horizontally disposed.
